(19) United States
(12) Patent Application Publication
(10) Pub. No.: US 2024/0099010 A1
(43) Pub. Date: Mar. 21, 2024

(54) SEMICONDUCTOR MEMORY DEVICE

(71) Applicant: Kioxia Corporation, Tokyo (JP)

(72) Inventors: Takamitsu ISHIHARA, Yokohama Kanagawa (JP); Kazuya MATSUZAWA, Kamakura Kanagawa (JP)

(21) Appl. No.: 18/459,353

(22) Filed: Aug. 31, 2023

(30) Foreign Application Priority Data
Sep. 21, 2022 (JP) 2022-150279

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A semiconductor memory device includes a gate electrode and a first and second semiconductor layer surrounding the gate electrode. A first electrode layer surrounds the gate electrode and contacts the first semiconductor layer. A second electrode layer surrounds the gate electrode and contacts the first and second semiconductor layers. The first semiconductor layer is between the first and second electrode layers. A third electrode layer surrounds the gate electrode and contacts the second semiconductor layer. The second semiconductor layer is between the second and third electrode layers. A first charge storage layer is between the gate electrode and the first semiconductor layer. A second charge storage layer is between the gate electrode and the second semiconductor layer.

### CROSS-REFERENCE TO RELATED APPLICATION

This application is based upon and claims the benefit of priority from Japanese Patent Application No. 2022-150279, filed Sep. 21, 2022, the entire contents of which are incorporated herein by reference.

### FIELD

Embodiments described herein relate generally to a semiconductor memory device.

### BACKGROUND

As one nonvolatile memory, there is a NOR flash memory. A NOR flash memory has excellent characteristics such as a fast read speed and random access capability as compared with, for example, a NAND flash memory. For example, in order to reduce manufacturing costs, it is expected that a degree of integration of the NOR flash memories will be improved.

### BRIEF DESCRIPTION OF THE DRAWINGS

FIG. 1 is a diagram illustrating a chip layout of a semiconductor memory device according to a first embodiment.

FIG. 2 is a circuit diagram of a memory cell array of a semiconductor memory device according to a first embodiment.

FIG. 3 is a schematic diagram of a memory cell array of a semiconductor memory device according to a first embodiment.

FIG. 4 is a schematic cross-sectional view of a memory cell array of a semiconductor memory device according to a first embodiment.

FIG. 5 is a schematic cross-sectional view of a memory cell array of a semiconductor memory device according to a first embodiment.

FIG. 6 is a schematic cross-sectional view of a memory cell array of a semiconductor memory device according to the first embodiment.

FIG. 7 is a schematic cross-sectional view of a memory cell of a semiconductor memory device according to a first embodiment.

FIG. 8 is a schematic cross-sectional view of a memory cell of a semiconductor memory device according to a first embodiment.

FIG. 9 is a schematic cross-sectional view of a memory cell of a semiconductor memory device according to a first embodiment.

FIGS. 10-21 are schematic cross-sectional views illustrating aspects of a method for manufacturing a semiconductor memory device according to a first embodiment.

FIG. 22 is a circuit diagram of a memory cell array of a semiconductor memory device according to a second embodiment.

FIG. 23 is a schematic diagram of a memory cell array of a semiconductor memory device according to a second embodiment.

FIG. 24 is a schematic cross-sectional view of a memory cell array of a semiconductor memory device according to a second embodiment.

FIG. 25 is a schematic cross-sectional view of a memory cell array of a semiconductor memory device according to a second embodiment.

### DETAILED DESCRIPTION

In general, according to one embodiment, a semiconductor memory device includes a first gate electrode layer extending in a first direction. A first semiconductor layer surrounds the first gate electrode layer. A second semiconductor layer is in the first direction from the first semiconductor layer and surrounds the first gate electrode layer. A first electrode layer surrounds the first gate electrode layer and is in contact with the first semiconductor layer. A second electrode layer is in the first direction from the first electrode layer. The second electrode layer surrounds the first gate electrode layer and is in contact with the first semiconductor layer and the second semiconductor layer. The first semiconductor layer is between the first electrode layer and the second electrode layer. A third electrode layer is in the first direction from the second electrode layer. The third electrode layer surrounds the first gate electrode layer and is in contact with the second semiconductor layer. The second semiconductor layer is between the second electrode layer and the third electrode layer. A conductive first charge storage layer is between the first gate electrode layer and the first semiconductor layer. A conductive second charge storage layer is between the first gate electrode layer and the second semiconductor layer.

Certain example embodiments are described below with reference to the drawings. It is noted that, in the following description, the same or substantially similar components or aspects are denoted by the same reference symbols, and descriptions of such component or aspects that have already been described may be omitted as appropriate from subsequent description. In addition, in the following, when components or aspects are provided in multiple instances of the same drawing or embodiment, then suffixes or the like (e.g., appended symbols with numbers/alphabet characters) may be added to a common or shared reference symbol for distinguishing between different instances of the otherwise similar components or aspects.

In addition, in this specification, terms “upper” and “lower” may be used for descriptive convenience. The terms “upper” and “lower” are terms generally indicating relative positional relationships in the drawings or the like. The terms “upper” and “lower” are not necessarily terms defining positional relationships with respect to gravity.

The qualitative analysis and quantitative analysis of the chemical composition of the materials constituting a semiconductor memory device can be implemented by performing, for example, secondary ion mass spectrometry (SIMS) and/or energy dispersive X-ray spectroscopy (EDX). In addition, for example, a transmission electron microscope (TEM) can be used to measure the thickness of components, layers, aspects, and the like constituting a semiconductor memory device as well as the distance between such components, layers, aspects, and the like.

### First Embodiment

A semiconductor memory device according to a first embodiment includes a first gate electrode layer extending in a first direction, a first semiconductor layer surrounding the first gate electrode layer, a second semiconductor layer provided in the first direction with respect to the first semiconductor layer and surrounding the first gate electrode layer, a first electrode layer surrounding the first gate electrode layer and being in contact with the first semiconductor layer, a second electrode layer provided in the first direction with respect to the first electrode layer, surrounding the first gate electrode layer, being in contact with the first semiconductor layer and the second semiconductor layer, and provided with the first semiconductor layer between the first electrode layer and the second electrode layer, a third electrode layer provided in the first direction with respect to the second electrode layer, surrounding the first gate electrode layer, being in contact with the second semiconductor layer, and provided with the second semiconductor layer between the second electrode layer and the third electrode layer, a conductive first charge storage layer provided between the first gate electrode layer and the first semiconductor layer, and a conductive second charge storage layer provided between the first gate electrode layer and the second semiconductor layer.

The semiconductor memory device according to the first embodiment is a flash memory 100. The flash memory 100 is a randomly accessible NOR flash memory. A memory cell of the flash memory 100 has a charge storage layer made of a conductor. The memory cells of the flash memory 100 are so-called floating gate type memory cells.

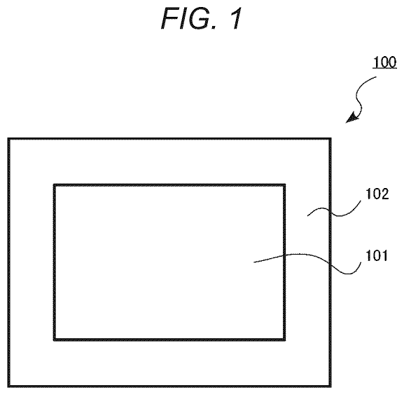

FIG. 1 is a diagram illustrating a chip layout of the semiconductor memory device according to the first embodiment. FIG. 1 is a top view of a flash memory 100. The flash memory 100 includes a memory cell array 101 and a peripheral circuit 102.

The memory cell array 101 includes a plurality of the memory cells arranged three-dimensionally. Each of the plurality of memory cells has a function of storing data.

The peripheral circuit 102 surrounds the memory cell array 101. The peripheral circuit 102 includes an electronic circuit for performing the operations related to the memory cells. For example, the peripheral circuit 102 is used to perform a read operation of data of a memory cell, a write operation of data to a memory cell, and an erasing operation of data of a memory cell.

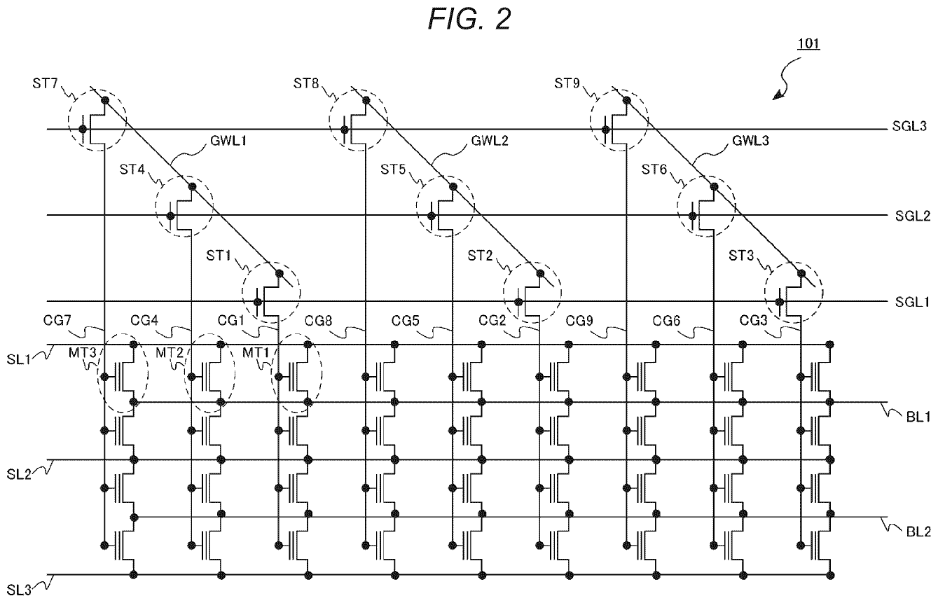

FIG. 2 is a circuit diagram of the memory cell array of the semiconductor memory device according to the first embodiment.

As illustrated in FIG. 2, the memory cell array 101 of the flash memory 100 of the first embodiment includes a plurality of memory cell transistors MT, a plurality of control gates CG, a plurality of source lines SL, a plurality of bit lines BL, a plurality of global word lines GWL, a plurality of select gate transistors ST, and a plurality of select gate lines SGL.

The plurality of control gates CG include, for example, a first control gate CG1, a second control gate CG2, a third control gate CG3, a fourth control gate CG4, a fifth control gate CG5, a sixth control gate CG6, a seventh control gate CG7, an eighth control gate CG8, and a ninth control gate CG9.

The plurality of source lines SL include, for example, a first source line SL1, a second source line SL2, and a third source line SL3. The plurality of bit lines BL include, for example, a first bit line BL1 and a second bit line BL2. The plurality of global word lines GWL include, for example, a first global word line GWL1, a second global word line GWL2, and a third global word line GWL3.

The plurality of select gate transistors ST include, for example, a first select gate transistor ST1, a second select gate transistor ST2, a third select gate transistor ST3, a fourth select gate transistor ST4, a fifth select gate transistor ST5, a sixth select gate transistor ST6, a seventh select gate transistor ST7, an eighth select gate transistor ST8, and a ninth select gate transistor ST9.

The first select gate transistor ST1 is an example of a first transistor. The second select gate transistor ST2 is an example of a second transistor. The fourth select gate transistor ST4 is an example of a third transistor.

The plurality of select gate lines SGL include, for example, a first select gate line SGL1, a second select gate line SGL2, and a third select gate line SGL3.

Each control gate CG is connected to gates of a plurality of memory cell transistors MT. FIG. 2 illustrates a case where the gates of the four memory cell transistors MT are connected to one control gate CG. One of a source and a drain of the memory cell transistors MT is connected to the source line SL, and the other is connected to a bit line BL.

A plurality of control gates CG are connected to one global word line GWL. FIG. 2 illustrates a case where the three control gates CG are connected to each global word line GWL.

A select gate transistor ST is provided between the global word line GWL and the control gate CG. The select gate transistor ST electrically connects the global word line GWL and a control gate CG. A select gate line SGL is connected to the gate of the select gate transistor ST.

For example, one control gate CG can be selected by selecting one global word line GWL and one select gate line SGL and turning on the select gate transistor ST. Furthermore, by selecting one source line SL and one bit line BL, one memory cell transistor MT can be selected and operated.

By selecting and operating one individual memory cell transistor MT, a read operation of data stored in the memory cell corresponding to the memory cell transistor MT or a write operation of data to the memory cell can be performed.

For example, by selecting the first global word line GWL1 and selecting the first select gate line SGL1, the first select gate transistor ST1 is turned on. By turning on the first select gate transistor ST1, the first control gate CG1 (connected to the first global word line GWL1) is selected. Furthermore, by selecting the first source line SL1 and the first bit line BL1, a first memory cell transistor MT1 surrounded by a dotted line in FIG. 2 can be selected and operated.

It is noted that, in the flash memory 100 of the first embodiment, the first memory cell transistor MT1 is connected to the same first global word line GWL1 as a second memory cell transistor MT2 that also shares the first source line SL1 and the first bit line BL1 with the first memory cell transistor MT1. The second memory cell transistor MT2 cannot be selected simultaneously with the first memory cell transistor MT1. Similarly, the first memory cell transistor MT1 is connected to the same first global word line GWL1 as a third memory cell transistor MT3 also sharing the first source line SL1 and the first bit line BL1 with the first memory cell transistor MT1 (and the second memory cell transistor MT2). The third memory cell transistor MT3 cannot be selected simultaneously with the first memory cell transistor MT1.

In other words, in the flash memory 100 of the first embodiment, the plurality of memory cells on the same xy plane that are connected to the same global word line GWL and share the same source line SL and bit line BL cannot be accessed simultaneously.

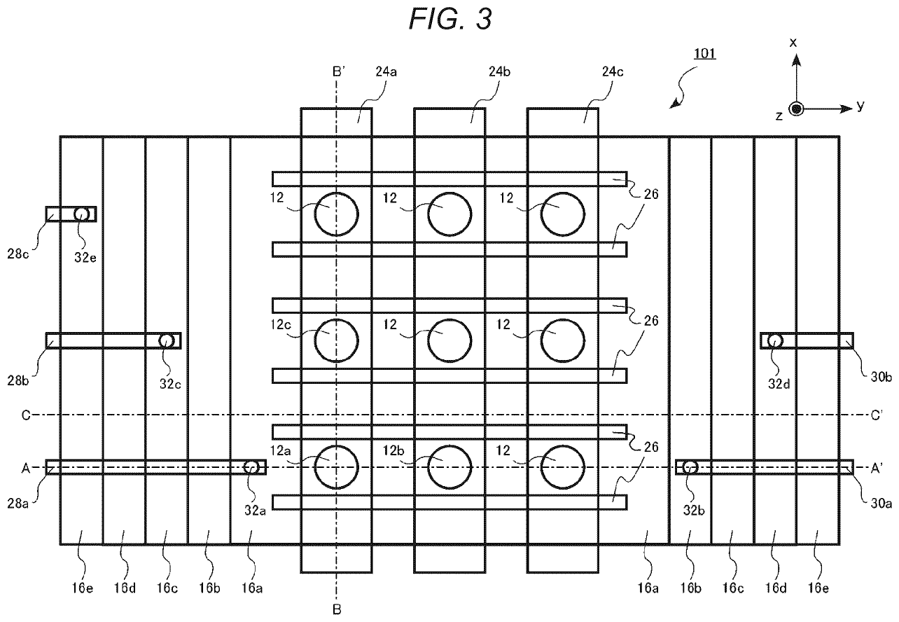

FIG. 3 is a schematic diagram of the memory cell array of the semiconductor memory device according to the first embodiment. FIG. 3 is a diagram illustrating a pattern layout of the memory cell array 101.

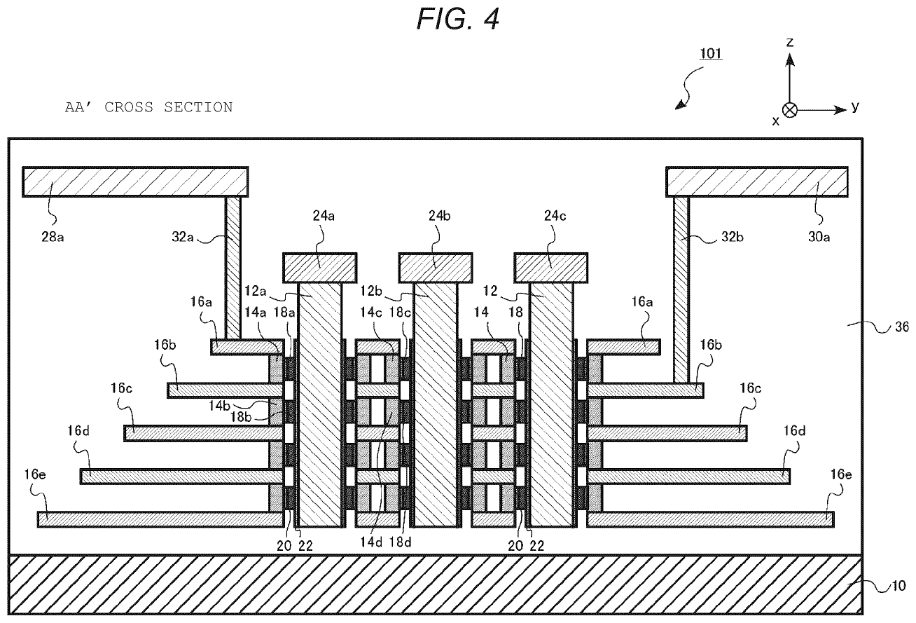

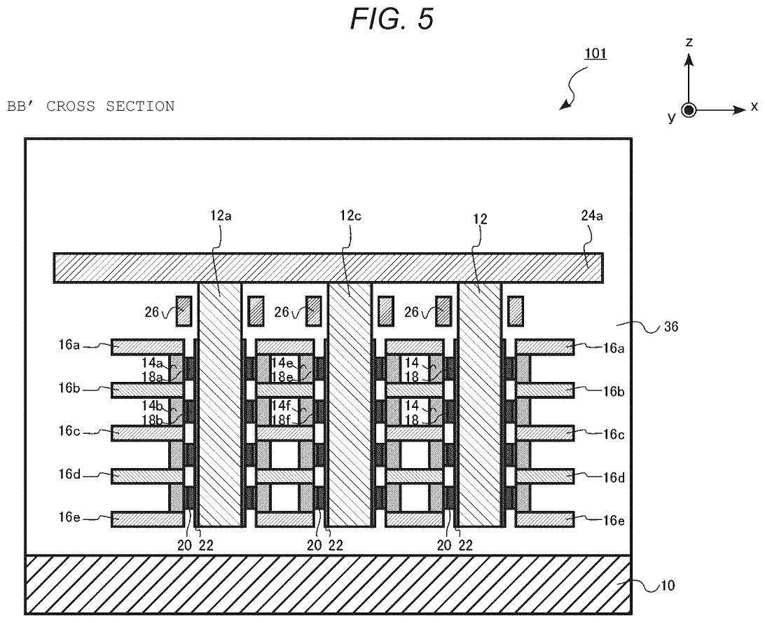

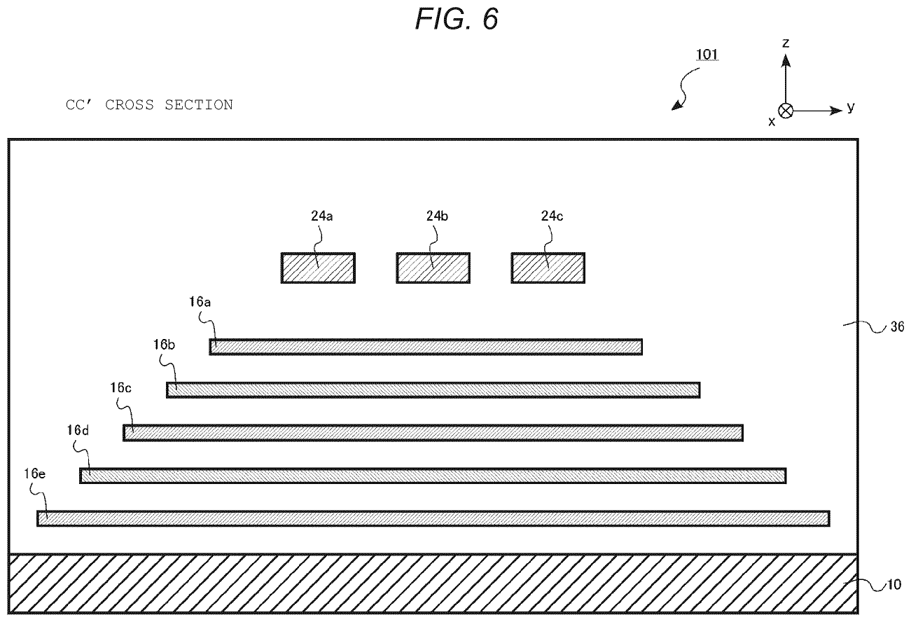

FIGS. 4, 5, and 6 are schematic cross-sectional views of the memory cell array of the semiconductor memory device according to the first embodiment. FIG. 4 is an AA′ cross section of FIG. 3. FIG. 5 is a BB′ cross section of FIG. 3. FIG. 6 is a CC′ cross section of FIG. 3.

In FIGS. 3, 4, 5, and 6, the x direction is an example of a third direction. The y direction is an example of a second direction. The z direction is an example of a first direction. The x, y, and z directions are orthogonal to each other.

FIG. 4 is a yz cross section of the memory cell array 101. FIG. 5 is an xz cross section of the memory cell array 101. FIG. 6 is a yz cross section of the memory cell array 101.

The memory cell array 101 of the flash memory 100 of the first embodiment includes a substrate 10, a plurality of gate electrode layers 12 (pillars), a plurality of semiconductor layers 14, a plurality of source/drain electrode layers 16, a plurality of charge storage layers 18, a tunnel insulating film 20, a block insulating film 22, a plurality of gate electrode wirings 24, a plurality of select gate wirings 26, a plurality of source lines 28, a plurality of bit lines 30, a plurality of contact plugs 32, and an interlayer insulating layer 36.

The tunnel insulating film 20 is an example of a first insulating film. The block insulating film 22 is an example of a second insulating film. The interlayer insulating layer 36 is an example of an insulating layer.

The plurality of gate electrode layers 12 include a first gate electrode layer 12a, a second gate electrode layer 12b, and a third gate electrode layer 12c. The first gate electrode layer 12a, the second gate electrode layer 12b, and the third gate electrode layer 12c functionally correspond to the first control gate CG1, the second control gate CG2, and the fourth control gate CG4, respectively, in the circuit diagram of FIG. 2.

The plurality of semiconductor layers 14 include a first semiconductor layer 14a, a second semiconductor layer 14b, a third semiconductor layer 14c, a fourth semiconductor layer 14d, a fifth semiconductor layer 14e, and a sixth semiconductor layer 14f.

The plurality of source/drain electrode layers 16 include a first source/drain electrode layer 16a, a second source/drain electrode layer 16b, a third source/drain electrode layer 16c, a fourth source/drain electrode layer 16d, and a fifth source/drain electrode layer 16e. The first source/drain electrode layer 16a is an example of a first electrode layer. The second source/drain electrode layer 16b is an example of a second electrode layer. The third source/drain electrode layer 16c is an example of a third electrode layer.

The first source/drain electrode layer 16a, the third source/drain electrode layer 16c, and the fifth source/drain electrode layer 16e functionally correspond to the first source line SL1, the second source line SL2, and the third source line SL3, respectively in the circuit diagram of FIG. 2. The second source/drain electrode layer 16b and the fourth source/drain electrode layer 16d functionally correspond to the first bit line BL1 and the second bit line BL2, respectively, in the circuit diagram of FIG. 2.

The plurality of charge storage layers 18 include a first charge storage layer 18a, a second charge storage layer 18b, a third charge storage layer 18c, a fourth charge storage layer 18d, a fifth charge storage layer 18e, and a sixth charge storage layers 18f.

The plurality of gate electrode wirings 24 include a first gate electrode wiring 24a, a second gate electrode wiring 24b, and a third gate electrode wiring 24c. The first gate electrode wiring 24a, the second gate electrode wiring 24b, and the third gate electrode wiring 24c functionally correspond to the first global word line GWL1, the second global word line GWL2, and the third global word line GWL3, respectively, in the circuit diagram of FIG. 2.

The plurality of source lines 28 include a first source line 28a, a second source line 28b, and a third source line 28c. The first source line 28a is an example of a first wiring. The second source line 28b is an example of a third wiring. The first source line 28a, the second source line 28b, and the third source line 28c functionally correspond to the first source line SL1, the second source line SL2, and the third source line SL3, respectively, in the circuit diagram of FIG. 2.

The plurality of bit lines 30 include a first bit line 30a and a second bit line 30b. The first bit line 30a is an example of a second wiring. The first bit line 30a and the second bit line 30b functionally correspond to the first bit line BL1 and the second bit line BL2, respectively, in the circuit diagram of FIG. 2.

The plurality of contact plugs 32 include a first contact plug 32a, a second contact plug 32b, a third contact plug 32c, a fourth contact plug 32d, and a fifth contact plug 32e. The first contact plug 32a is an example of a first conductive layer. The second contact plug 32b is an example of a second conductive layer. The third contact plug 32c is an example of a third conductive layer.

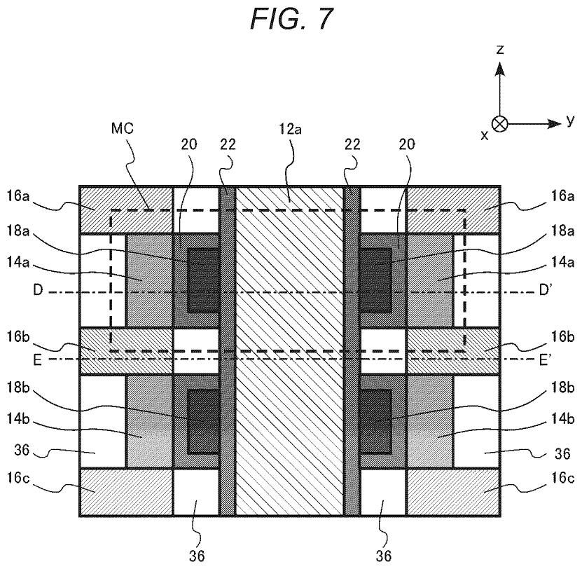

FIGS. 7, 8, and 9 are schematic cross-sectional views of the memory cells of the semiconductor memory device according to the first embodiment. FIG. 7 is an enlarged view of a portion depicted in FIG. 4. FIG. 7 includes two memory cells. A region surrounded by a dotted frame in FIG. 7 corresponds to one memory cell MC.

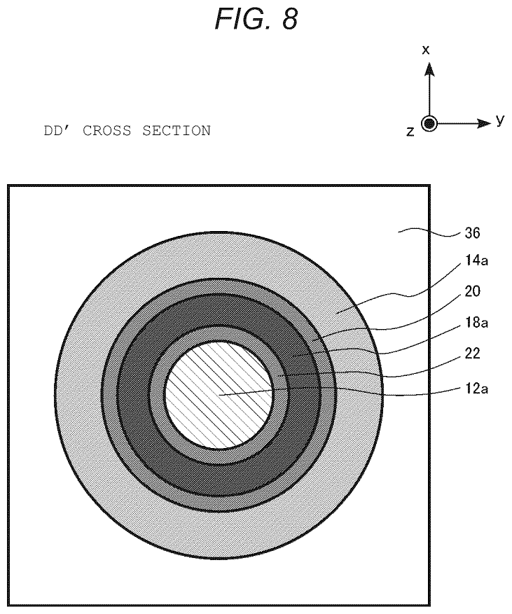

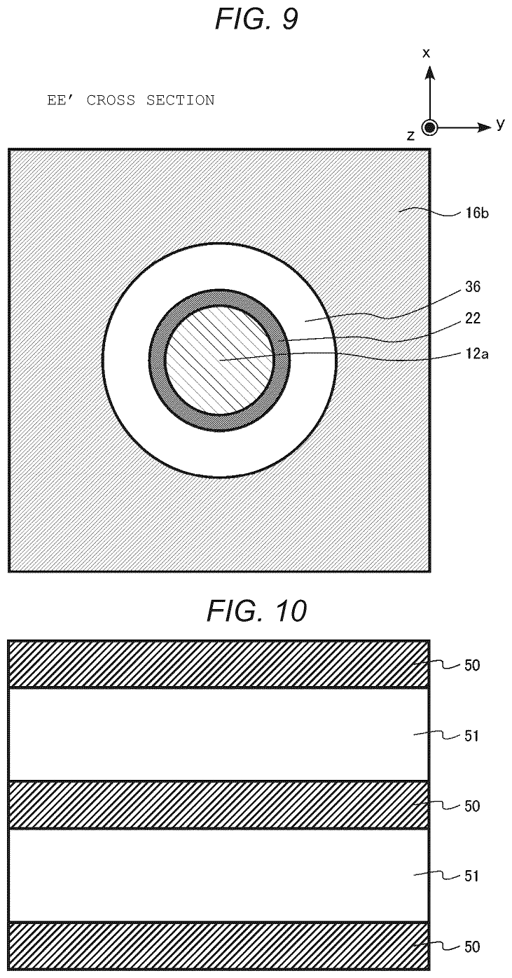

FIG. 8 is a DD′ cross section of FIG. 7. FIG. 9 is an EE′ cross section of FIG. 7.

The substrate 10 is, for example, a semiconductor substrate. The substrate 10 is made of, for example, monocrystalline silicon. The substrate 10 may be, for example, an insulating substrate made of an insulator.

The substrate 10 has a front (upper) surface parallel to the x and y directions. The direction perpendicular to the front surface of the substrate 10 is the z direction.

The gate electrode layer 12 is provided on the substrate 10. The gate electrode layer 12 extends in the z direction perpendicular to the front surface of the substrate 10. The gate electrode layer 12 penetrates through the plurality of source/drain electrode layers 16.

The gate electrode layers 12 are repeatedly arranged in the x direction and the y direction in what may be referred to as rows and columns. For example, the second gate electrode layer 12b is provided in the y direction from the first gate electrode layer 12a. The third gate electrode layer 12c is provided in the x direction from the first gate electrode layer 12a.

The gate electrode layer 12 functions as a gate electrode of the memory cell transistor MT.

The gate electrode layer 12 is a conductor. The gate electrode layer 12 can comprise, for example, polycrystalline silicon, amorphous silicon, or monocrystalline silicon. The gate electrode layer 12 is, for example, silicon containing p-type impurities or silicon containing n-type impurities.

The gate electrode layer 12 has a columnar shape. The gate electrode layer 12 has, for example, a cylindrical shape.

The semiconductor layer 14 surrounds the gate electrode layer 12. The first semiconductor layer 14a surrounds the first gate electrode layer 12a. The second semiconductor layer 14b surrounds the first gate electrode layer 12a. The third semiconductor layer 14c surrounds the second gate electrode layer 12b. The fourth semiconductor layer 14d surrounds the second gate electrode layer 12b. The fifth semiconductor layer 14e surrounds the third gate electrode layer 12c. The sixth semiconductor layer 14f surrounds the third gate electrode layer 12c.

The semiconductor layer 14 functions as a channel of the memory cell transistor MT. In the memory cell transistor MT, the semiconductor layer 14 serving as a channel surrounds the gate electrode layer 12.

The semiconductor layer 14 comprises, for example, polycrystalline silicon, amorphous silicon, or monocrystalline silicon. The semiconductor layer 14 can be polycrystalline silicon, amorphous silicon, or monocrystalline silicon. The semiconductor layer 14 is, for example, undoped silicon into which conductive impurities are not intentionally introduced. The n-type impurity concentration or the p-type impurity concentration in the semiconductor layer 14 is, for example, 1×10¹⁴ cm⁻³ or less.

The z direction thickness of the semiconductor layer 14 is, for example, 10 nm to 100 nm. The thickness of the semiconductor layer 14 between the tunnel insulating film 20 and the interlayer insulating layer 36 is, for example, thinner than the thickness of the semiconductor layer 14 in the z direction.

The source/drain electrode layer 16 is provided on the substrate 10. The source/drain electrode layers 16 are repeatedly provided in the z direction.

The source/drain electrode layer 16 surrounds the gate electrode layer 12. The semiconductor layer 14 is provided between the two source/drain electrode layers 16 adjacent to each other in the z direction. The two source/drain electrode layers 16 adjacent to each other in the z direction are in contact with the semiconductor layer 14 provided therebetween.

For example, the first source/drain electrode layer 16a surrounds the first gate electrode layer 12a. The second source/drain electrode layer 16b surrounds the first gate electrode layer 12a. The third source/drain electrode layer 16c surrounds the first gate electrode layer 12a.

For example, the first semiconductor layer 14a is provided between the first source/drain electrode layer 16a and the second source/drain electrode layer 16b. The first source/drain electrode layer 16a and the second source/drain electrode layer 16b are in contact with the first semiconductor layer 14a.

For example, the second semiconductor layer 14b is provided between the second source/drain electrode layer 16b and the third source/drain electrode layer 16c. The second source/drain electrode layer 16b and the third source/drain electrode layer 16c are in contact with the second semiconductor layer 14b.

For example, the third semiconductor layer 14c is provided between the first source/drain electrode layer 16a and the second source/drain electrode layer 16b. The first source/drain electrode layer 16a and the second source/drain electrode layer 16b are in contact with the third semiconductor layer 14c.

For example, the fourth semiconductor layer 14d is provided between the second source/drain electrode layer 16b and the third source/drain electrode layer 16c. The second source/drain electrode layer 16b and the third source/drain electrode layer 16c are in contact with the fourth semiconductor layer 14d.

For example, the fifth semiconductor layer 14e is provided between the first source/drain electrode layer 16a and the second source/drain electrode layer 16b. The first source/drain electrode layer 16a and the second source/drain electrode layer 16b are in contact with the fifth semiconductor layer 14e.

For example, the sixth semiconductor layer 14f is provided between the second source/drain electrode layer 16b and the third source/drain electrode layer 16c. The second source/drain electrode layer 16b and the third source/drain electrode layer 16c are in contact with the sixth semiconductor layer 14f.

The source/drain electrode layer 16 functions as source/drain electrodes of the memory cell transistors MT.

The source/drain electrode layer 16 is a conductor or a semiconductor material. The source/drain electrode layer 16 comprises, for example, polycrystalline silicon, amorphous silicon, or monocrystalline silicon. The source/drain electrode layer 16 is, for example, silicon containing p-type impurities or silicon containing n-type impurities.

The source/drain electrode layer 16 can be or comprise a metal in some examples. The source/drain electrode layer 16 comprises, for example, tungsten, molybdenum, or titanium nitride. The source/drain electrode layer 16 is, for example, tungsten, molybdenum, or titanium nitride.

The source/drain electrode layer 16 has, for example, a plate shape.

The interlayer insulating layer 36 is provided between two source/drain electrode layers 16 adjacent to each other in the z direction.

The source/drain electrode layer 16 has a staircase structure at the end of the memory cell array 101, as illustrated in FIGS. 4 and 6.

A width of the source/drain electrode layer 16 in the y direction increases as it approaches the substrate 10. The width of the source/drain electrode layer 16 in the y direction increases as the distance from the gate electrode wiring 24 increases.

For example, a width of the second source/drain electrode layer 16b in the y direction is greater than a width of the first source/drain electrode layer 16a in the y direction. A width of the third source/drain electrode layer 16c in the y direction is greater than a width of the second source/drain electrode layer 16b in the y direction.

The charge storage layer 18 is provided between the gate electrode layer 12 and the semiconductor layer 14. The charge storage layer 18 surrounds the gate electrode layer 12.

For example, the first charge storage layer 18a is provided between the first gate electrode layer 12a and the first semiconductor layer 14a. For example, the second charge storage layer 18b is provided between the first gate electrode layer 12a and the second semiconductor layer 14b.

For example, the third charge storage layer 18c is provided between the second gate electrode layer 12b and the third semiconductor layer 14c. For example, the fourth charge storage layer 18d is provided between the second gate electrode layer 12b and the fourth semiconductor layer 14d.

For example, the fifth charge storage layer 18e is provided between the third gate electrode layer 12c and the fifth semiconductor layer 14e. For example, the sixth charge storage layer 18f is provided between the third gate electrode layer 12c and the sixth semiconductor layer 14f.

The charge storage layer 18 is provided between the tunnel insulating film 20 and the block insulating film 22.

The two charge storage layers 18 adjacent to each other in the z direction are separated. The interlayer insulating layer 36 is provided between the two charge storage layers 18 adjacent to each other in the z direction.

For example, the first charge storage layer 18a and the second charge storage layer 18b are separated in the z direction. The interlayer insulating layer 36 is provided between the first charge storage layer 18a and the second charge storage layer 18b.

The charge storage layer 18 has a function of storing charges. The charge is, for example, an electron. A threshold voltage of the memory cell transistor MT changes according to the amount of the charges stored in the charge storage layer 18. By using this change in threshold voltage, one memory cell MC can store data. As the amount of the charges stored in the charge storage layer 18 increases, the amount of change in the threshold voltage increases.

For example, when the threshold voltage of the memory cell transistor MT changes, the voltage at which the memory cell transistor MT turns on changes. For example, when a state of high threshold voltage is defined as data of “0” and a state of low threshold voltage is defined as data of “1”, the memory cell can store 1-bit data of “0” and “1”.

The charge storage layer 18 can be a conductor or a semiconductor. The charge storage layer 18 is, for example, polycrystalline silicon, amorphous silicon, or monocrystalline silicon. The charge storage layer 18 can be, for example, silicon containing p-type impurities or silicon containing n-type impurities.

In some examples, charge storage layer 18 can be or comprise a metal. The charge storage layer 18 can comprise, for example, tungsten, molybdenum, or titanium nitride. For example, charge storage layer 18 is tungsten, molybdenum, or titanium nitride.

The tunnel insulating film 20 is provided between the charge storage layer 18 and the semiconductor layer 14. The tunnel insulating film 20 surrounds the charge storage layer 18.

For example, the tunnel insulating film 20 is provided between the first charge storage layer 18a and the first semiconductor layer 14a. The tunnel insulating film 20 surrounds, for example, the first charge storage layer 18a.

The tunnel insulating film 20 has a function of passing the charges between the semiconductor layer 14 and the charge storage layer 18.

The tunnel insulating film 20 is, for example, an oxide, an oxynitride, or a nitride, for example, silicon oxide, silicon nitride, or silicon oxynitride. In an example, tunnel insulating film 20 is a silicon oxide film.

The block insulating film 22 is provided between the charge storage layer 18 and the gate electrode layer 12. The block insulating film 22 surrounds the gate electrode layer 12.

For example, the block insulating film 22 is provided between the first charge storage layer 18a and the first gate electrode layer 12a. The block insulating film 22 surrounds the first gate electrode layer 12a.

The block insulating film 22 has a function of blocking current flowing between the charge storage layer 18 and the gate electrode layer 12.

The block insulating film 22 can be, for example, an oxide, an oxynitride, or a nitride. For example, block insulating film 22 may be or comprise silicon oxide or aluminum oxide.

The gate electrode wiring 24 extends in the x direction. For example, the first gate electrode wiring 24a extends in the x direction. For example, the second gate electrode wiring 24b extends in the x direction.

The select gate transistor ST is provided between the gate electrode wiring 24 and the gate electrode layer 12. The select gate transistor ST is electrically connected to the gate electrode wiring 24 and the gate electrode layer 12.

For example, the first select gate transistor ST1 is provided between the first gate electrode wiring 24a and the first gate electrode layer 12a. The first select gate transistor ST1 is electrically connected to the first gate electrode wiring 24a and the first gate electrode layer 12a. It is noted that, in the circuit diagram of FIG. 2, the first gate electrode wiring 24a and the first gate electrode layer 12a correspond to the first global word line GWL1 and the first control gate CG1, respectively.

For example, the second select gate transistor ST2 is provided between the second gate electrode wiring 24b and the second gate electrode layer 12b. The second select gate transistor ST2 is electrically connected to the second gate electrode wiring 24b and the second gate electrode layer 12b. It is noted that, in the circuit diagram of FIG. 2, the second gate electrode wiring 24b and the second gate electrode layer 12b correspond to the second global word line GWL2 and the second control gate CG2, respectively.

For example, the fourth select gate transistor ST4 is provided between the first gate electrode wiring 24a and the third gate electrode layer 12c. The fourth select gate transistor ST4 is electrically connected to the first gate electrode wiring 24a and the third gate electrode layer 12c. It is noted that, in the circuit diagram of FIG. 2, the first gate electrode wiring 24a and the third gate electrode layer 12c correspond to the first global word line GWL1 and the fourth control gate CG4, respectively.

The select gate transistor ST functions as a switching transistor that switches between a conducting state and a non-conducting state in the path between the gate electrode wiring 24 and the gate electrode layer 12.

The select gate wiring 26 extends in a direction intersecting the gate electrode wiring 24. The select gate wiring 26 extends in the y direction. The select gate wiring 26 faces the gate electrode layer 12. It is noted that, although FIGS. 3 and 5 depict a structure in which the select gate wiring 26 is divided into separate portions on both sides of each gate electrode layer 12, in other examples a surrounded gate transistor structure in which a select gate wiring 26 surrounds each gate electrode layer 12 may be provided.

The select gate wiring 26 functions as a gate electrode of the select gate transistor ST.

The source line 28 is provided on the source/drain electrode layer 16. The source line 28 is provided in the z direction from the source/drain electrode layer 16. The source line 28 is electrically connected to a portion of the source/drain electrode layers 16 among the plurality of source/drain electrode layers 16.

The first source line 28a is electrically connected to the first source/drain electrode layer 16a. The second source line 28b is electrically connected to the third source/drain electrode layer 16c. The third source line 28c is electrically connected to the fifth source/drain electrode layer 16e.

The bit line 30 is provided on the source/drain electrode layer 16. The bit line 30 is provided in the z direction from the source/drain electrode layer 16. The bit line 30 is electrically connected to a portion of the source/drain electrode layers 16 among the plurality of source/drain electrode layers 16.

The first bit line 30a is electrically connected to the second source/drain electrode layer 16b. The second bit line 30b is electrically connected to the fourth source/drain electrode layer 16d.

The contact plug 32 is provided on the source/drain electrode layer 16. The contact plug 32 extends in the z direction.

A portion of the contact plugs 32 are provided between the source/drain electrode layers 16 and the source lines 28 and electrically connect a source/drain electrode layer 16 and a source line 28.

Another portion of the contact plugs 32 are provided between the source/drain electrode layers 16 and the bit lines 30 and electrically connect a source/drain electrode layer 16 and a bit line 30.

The first contact plug 32a is provided between the first source/drain electrode layer 16a and the first source line 28a. The first contact plug 32a is electrically connected to the first source/drain electrode layer 16a and the first source line 28a.

The second contact plug 32b is provided between the second source/drain electrode layer 16b and the first bit line 30a. The second contact plug 32b is electrically connected to the second source/drain electrode layer 16b and the first bit line 30a.

The third contact plug 32c is provided between the third source/drain electrode layer 16c and the second source line 28b. The third contact plug 32c is electrically connected to the third source/drain electrode layer 16c and the second source line 28b.

The fourth contact plug 32d is provided between the fourth source/drain electrode layer 16d and the second bit line 30b. The fourth contact plug 32d is electrically connected to the fourth source/drain electrode layer 16d and the second bit line 30b.

The fifth contact plug 32e is provided between the fifth source/drain electrode layer 16e and the third source line 28c. The fifth contact plug 32e is electrically connected to the fifth source/drain electrode layer 16e and the third source line 28c.

The first contact plug 32a, the third contact plug 32c, and the fifth contact plug 32e are connected to the first end of the source/drain electrode layer 16 in the y direction. The second contact plug 32b and the fourth contact plug 32d are connected to the second end of the source/drain electrode layer 16 opposite to the first end in the y direction.

For example, a distance between the first contact plug 32a and the first gate electrode layer 12a in the y direction is less than a distance between the first contact plug 32a and the second gate electrode layer 12b in the y direction. A distance between the second contact plug 32b and the first gate electrode layer 12a in the y direction is greater than a distance between the second contact plug 32b and the second gate electrode layer 12b in the y direction. A distance between the third contact plug 32c and the first gate electrode layer 12a in the y direction is less than a distance between the third contact plug 32c and the second gate electrode layer 12b in the y direction.

For example, the gate electrode wiring 24 is provided between the first contact plug 32a and the second contact plug 32b in the y direction.

The interlayer insulating layer 36 has a function of electrically insulating between conductors provided in the memory cell array 101.

The interlayer insulating layer 36 surrounds, for example, the semiconductor layers 14. The interlayer insulating layer 36 is provided, for example, between the semiconductor layers 14 otherwise adjacent to each other in the y direction or x direction.

The interlayer insulating layer 36 is provided, for example, between otherwise adjacent charge storage layers 18 in the z direction. The interlayer insulating layer 36 is provided, for example, between the source/drain electrode layers 16 otherwise adjacent to each other in the z direction.

The interlayer insulating layer 36 is, for example, an oxide, an oxynitride, or a nitride. The interlayer insulating layer 36 is, for example, silicon oxide, silicon nitride, or silicon oxynitride.

Next, an example of a method for manufacturing the semiconductor memory device according to the first embodiment will be described.

FIGS. 10, 11, 12, 13, 14, 15, 16, 17, 18, 19, 20, and 21 are schematic cross-sectional views illustrating a method for manufacturing the semiconductor memory device according to the first embodiment. FIGS. 10 to 21 illustrate the respective cross sections corresponding in general to FIG. 7. FIGS. 10 to 21 are diagrams illustrating an example of a method for manufacturing the memory cell array 101 of the semiconductor memory device.

First, a silicon nitride layer 50 and a silicon oxide layer 51 are alternately stacked on a substrate (FIG. 10).

The silicon nitride layer 50 and the silicon oxide layer 51 are formed by, for example, a chemical vapor deposition method (CVD method). A portion of the silicon oxide layer 51 eventually becomes the interlayer insulating layer 36.

Next, memory holes 53 are formed in the silicon nitride layer 50 and the silicon oxide layer 51 (FIG. 11). The memory hole 53 penetrates through the silicon nitride layer 50 and the silicon oxide layer 51. The memory hole 53 is formed by, for example, a lithography method and a reactive ion etching method (RIE method).

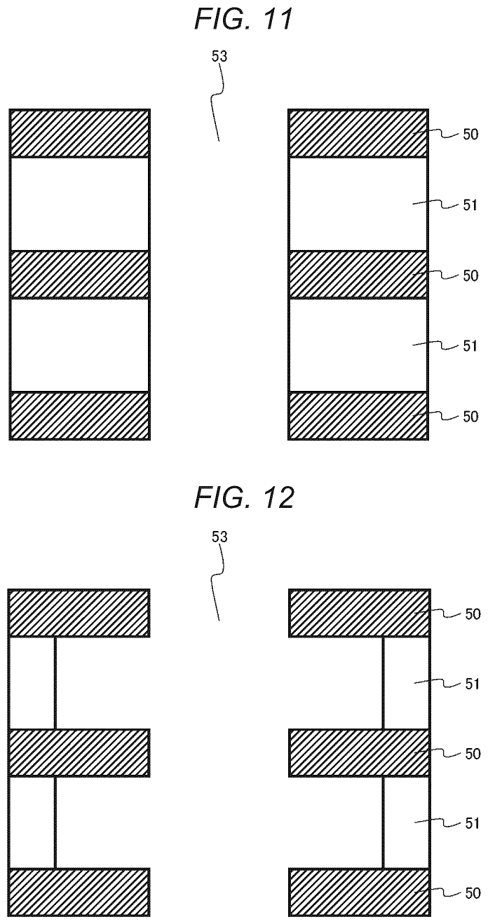

Next, a part of the silicon oxide layer 51 is laterally recessed from the inside of the memory hole 53 (FIG. 12). A recess portion is formed in an inner wall of the memory hole 53. The silicon oxide layer 51 is removed, for example, by a wet etching method.

Next, a first amorphous silicon film 54 is deposited on the inner wall of the memory hole 53 (FIG. 13). The first amorphous silicon film 54 fills the recess portion formed in the inner wall of the memory hole 53.

The first amorphous silicon film 54 is a undoped film containing no conductive impurities. The first amorphous silicon film 54 is formed by, for example, a CVD method. The first amorphous silicon film 54 eventually becomes the semiconductor layer 14.

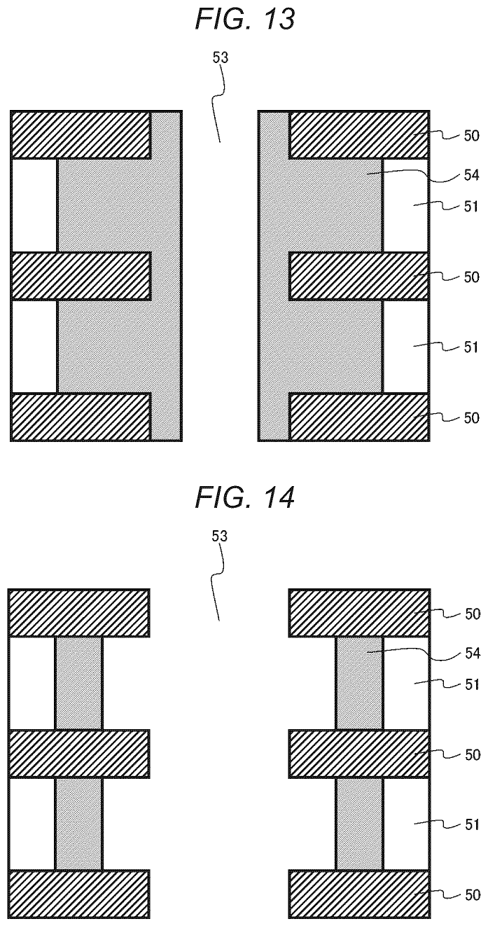

Next, the first amorphous silicon film 54 on the front surface of the inner wall of the memory hole 53 is removed (FIG. 14). The first amorphous silicon film 54 remains in a portion of the recess portion of the memory hole 53. The first amorphous silicon film 54 is removed by, for example, isotropic dry etching.

Next, a first silicon oxide film 55 and a second amorphous silicon film 56 are formed in the recess portion of the memory hole 53 (FIG. 15). The second amorphous silicon film 56 can be a conductor containing conductive impurities.

For example, after forming the first silicon oxide film 55 and the second amorphous silicon film 56 by a CVD method, the first silicon oxide film 55 and the second amorphous silicon film 56 on the front surface of the inner wall of the memory hole 53 are removed by a RIE method.

The first silicon oxide film 55 eventually becomes the tunnel insulating film 20. The second amorphous silicon film 56 eventually becomes the charge storage layer 18.

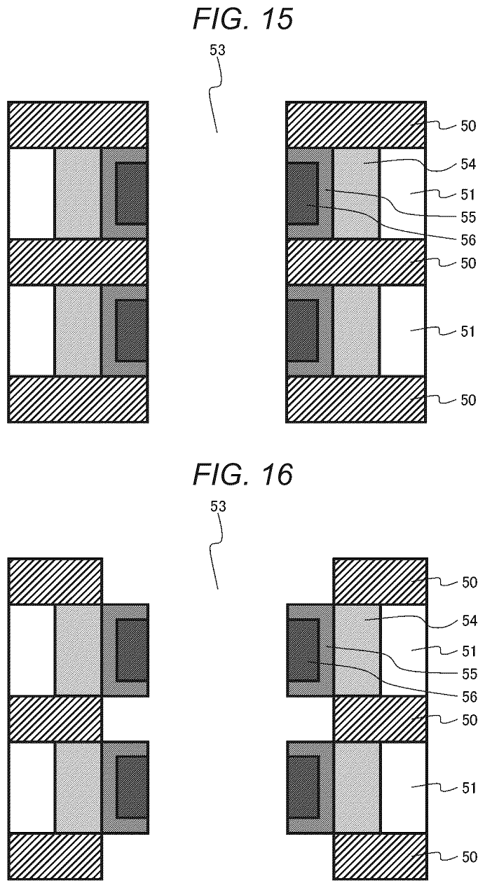

Next, a portion of the silicon nitride layer 50 is laterally recessed from the inside of the memory hole 53 (FIG. 16). The recess portion is formed in the inner wall of the memory hole 53. A portion of the silicon nitride layer 50 is removed by, for example, isotropic dry etching.

Next, a second silicon oxide film 57 is formed in the recess portion of the memory hole 53 (FIG. 17). For example, after forming the second silicon oxide film 57 by a CVD method, the second silicon oxide film 57 on the front surface of the inner wall of the memory hole 53 is removed by a RIE method. The second silicon oxide film 57 eventually becomes part of the interlayer insulating layer 36.

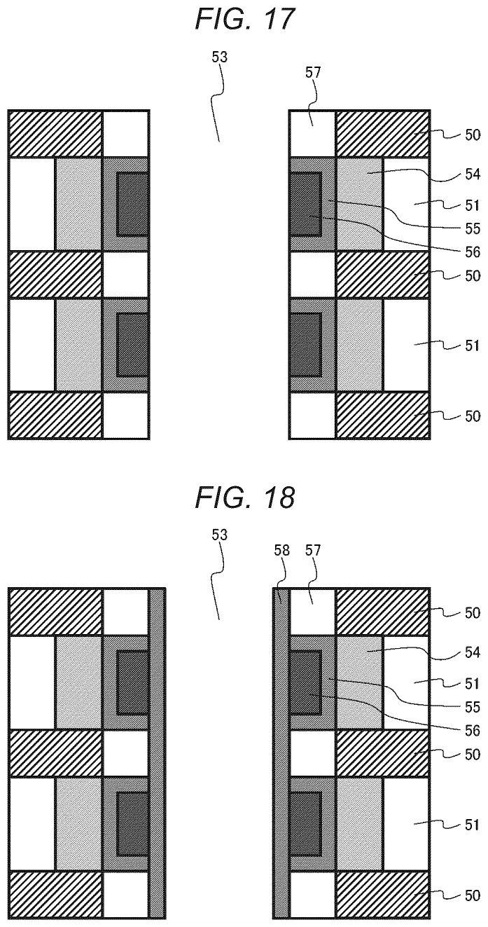

Next, an aluminum oxide film 58 is formed on the inner wall of the memory hole 53 (FIG. 18). The aluminum oxide film 58 is formed by, for example, a CVD method. The aluminum oxide film 58 eventually becomes the block insulating film 22.

Next, the memory holes 53 are filled (embedded) with a third amorphous silicon film 60 (FIG. 19). The third amorphous silicon film 60 is a conductor containing conductive impurities. The third amorphous silicon film 60 is formed by, for example, a CVD method. The third amorphous silicon film 60 eventually becomes the gate electrode layer 12.

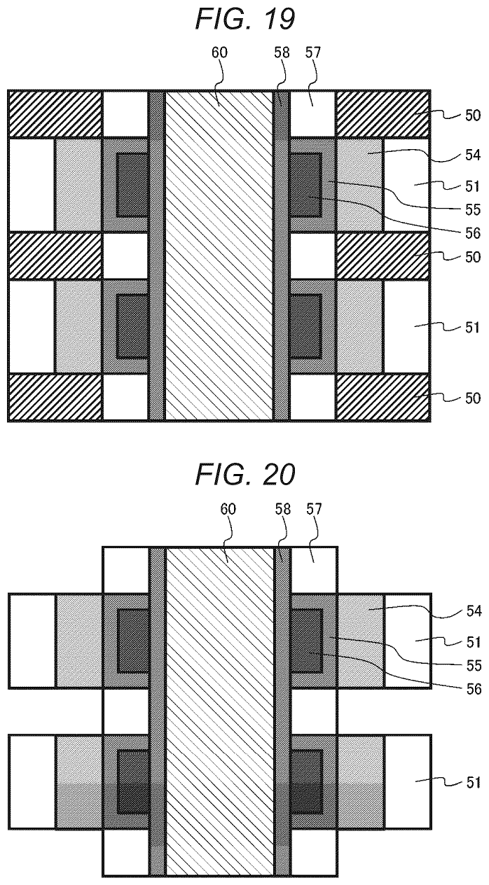

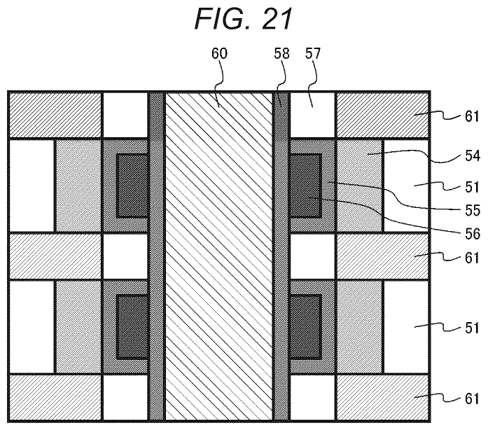

Next, by using an etched groove, the silicon nitride layer 50 can be selectively removed by wet etching (FIG. 20). The silicon nitride layer 50 is selectively etched with respect to the silicon oxide layer 51, the first amorphous silicon film 54, and the second silicon oxide film 57.

Next, a fourth amorphous silicon film 61 is formed in the region from which the silicon nitride layer 50 is removed (FIG. 21). The fourth amorphous silicon film 61 is a conductor containing conductive impurities. The fourth amorphous silicon film 61 is formed by, for example, a CVD method. The fourth amorphous silicon film 61 eventually becomes the source/drain electrode layer 16. It is noted that crystallization annealing for crystallizing the first or fourth amorphous silicon film may be added to the process in some examples.

After that, a pillar of a fifth amorphous silicon film connected on the third amorphous silicon film 60 can be formed. The concentration of conductive impurities in the fifth amorphous silicon film is lower than the concentration of conductive impurities in the third amorphous silicon film 60. Then, a silicon oxide layer is formed on a side surface of the pillar of the fifth amorphous silicon film. Furthermore, a sixth amorphous silicon film is formed with a silicon oxide layer interposed between the pillars of the fifth amorphous silicon film and the sixth amorphous silicon film.

The pillar of the fifth amorphous silicon film eventually becomes the channel of the select gate transistor ST. In addition, the silicon oxide layer becomes the gate insulating layer of the select gate transistor ST. The sixth amorphous silicon film eventually becomes the gate electrode of the select gate transistor ST, that is, the select gate wiring 26.

By the manufacturing method described above, the memory cell array 101 of the semiconductor memory device according to the first embodiment is manufactured.

Next, functions and effects of the semiconductor memory device according to the first embodiment will be described.

A NOR flash memory has excellent characteristics such as a fast read speed and random access capability as compared to, for example, a NAND flash memory. However, in order to reduce manufacturing costs, it is expected that the degree of integration of the NOR flash memories will need to be improved.

In the flash memory 100 of the first embodiment, the plurality of memory cells MC are three-dimensionally arranged in the memory cell array 101. Therefore, the degree of integration is improved as compared to, for example, a flash memory in which the plurality of memory cells MC are only two-dimensionally arranged. Therefore, for example, the manufacturing cost of the flash memory 100 can be reduced.

In addition, the source/drain regions of the memory cell transistor MT of the flash memory 100 can be formed of a semiconductor film containing conductive impurities or a metal film. Therefore, for example, the junction of the source/drain regions can be shallower as compared with a case where the source/drain regions are formed by using an ion implantation method. Therefore, a short-channel effect of a memory cell transistor MT can be prevented.

By preventing the short-channel effect for the memory cell transistors MT, a gate length of the memory cell transistors MT can be reduced, and the degree of integration (miniaturization) of the flash memory 100 can be improved. In addition, the reduction in thermal electron write efficiency due to the short-channel effect is avoided, and a flash memory 100 with excellent write characteristics can be implemented.

The source/drain electrode layer 16 is preferably made of metal from the viewpoint of providing a shallower junction for the source/drain regions and preventing the short-channel effect.

As described above, according to the first embodiment, a NOR flash memory capable of improving the degree of integration can be provided.

### Second Embodiment

A semiconductor memory device according to a second embodiment differs from the semiconductor memory device according to the first embodiment in that the semiconductor memory device according to the second embodiment further includes a fifth semiconductor layer surrounding the third gate electrode layer, a sixth semiconductor layer provided in the first direction with respect to the fifth semiconductor layer and surrounding the third gate electrode layer, a fourth electrode layer separated from the first electrode layer in the third direction, surrounding the third gate electrode layer, and being in contact with the fifth semiconductor layer, a fifth electrode layer separated from the second electrode layer in the third direction, surrounding the third gate electrode layer, being in contact with the fifth semiconductor layer and the sixth semiconductor layer, and provided with the fifth semiconductor layer between the fourth electrode layer and the fifth electrode layer, a sixth electrode layer separated from the third electrode layer in the third direction, surrounding the third gate electrode layer, being in contact with the sixth semiconductor layer, and provided with the sixth semiconductor layer between the fifth electrode layer and the sixth electrode layer, a conductive fifth charge storage layer provided between the third gate electrode layer and the fifth semiconductor layer, and a conductive sixth charge storage layer provided between the third gate electrode layer and the sixth semiconductor layer. Specifically, the semiconductor memory device according to the second embodiment differs from the semiconductor memory device according to the first embodiment in that the source/drain regions are divided in the x direction. In the following, a portion of the description may be omitted for contents overlapping with the first embodiment.

The semiconductor memory device according to the second embodiment is a flash memory 200. The flash memory 200 is a randomly accessible NOR flash memory. The memory cell of the flash memory 200 has a charge storage layer made of a conductor. The memory cells of the flash memory 200 are so-called floating gate type memory cells.

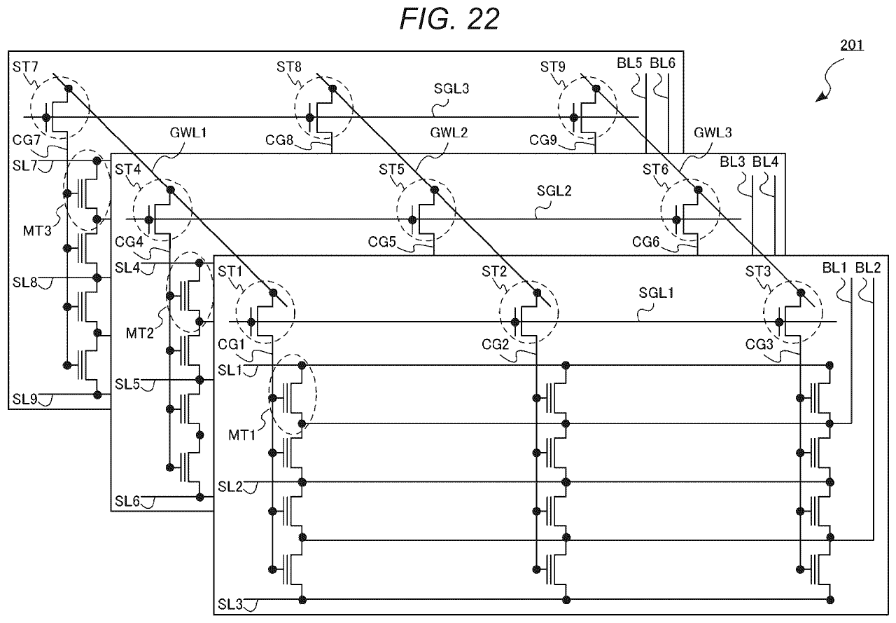

FIG. 22 is a circuit diagram of the memory cell array of the semiconductor memory device according to the second embodiment.

As illustrated in FIG. 22, the memory cell array 201 of the flash memory 200 of the second embodiment includes a plurality of memory cell transistors MT, a plurality of control gates CG, a plurality of source lines SL, a plurality of bit lines BL, a plurality of global word line GWL, a plurality of select gate transistors ST, and a plurality of select gate lines SGL.

The plurality of control gates CG include, for example, a first control gate CG1, a second control gate CG2, a third control gate CG3, a fourth control gate CG4, a fifth control gate CG5, a sixth control gate CG6, a seventh control gate CG7, an eighth control gate CG8, and a ninth control gate CG9.

The plurality of source lines SL include, for example, a first source line SL1, a second source line SL2, a third source line SL3, a fourth source line SL4, a fifth source line SL5, a sixth source line SL6, a seventh source line SL7, an eighth source line SL8, and a ninth source line SL9. The plurality of bit lines BL include, for example, a first bit line BL1, a second bit line BL2, a third bit line BL3, a fourth bit line BL4, a fifth bit line BL5, and a sixth bit line BL6. In addition, the plurality of global word lines GWL include, for example, a first global word line GWL1, a second global word line GWL2, and a third global word line GWL3.

The plurality of select gate transistors ST include, for example, a first select gate transistor ST1, a second select gate transistor ST2, a third select gate transistor ST3, a fourth select gate transistor ST4, a fifth select gate transistor ST5, a sixth select gate transistor ST6, a seventh select gate transistor ST7, an eighth select gate transistor ST8, and a ninth select gate transistor ST9. The first select gate transistor ST1 is an example of a first transistor. The second select gate transistor ST2 is an example of a second transistor. The fourth select gate transistor ST4 is an example of a third transistor.

The plurality of select gate lines SGL include, for example, a first select gate line SGL1, a second select gate line SGL2, and a third select gate line SGL3.

Each control gate CG is connected to gates of a plurality of memory cell transistors MT. FIG. 22 illustrates a case where the gates of four memory cell transistors MT are connected to one control gate CG. One of the source and drain of each memory cell transistor MT is connected to the source line SL, and the other is connected to the bit line BL.

A plurality of control gates CG are connected to each global word line GWL. FIG. 22 illustrates a case where the three control gates CG are connected to one global word line GWL.

A select gate transistor ST is provided between a global word line GWL and a control gate CG. The select gate transistor ST electrically connects the global word line GWL and the control gate CG. The select gate line SGL is connected to the gate of the select gate transistor ST.

For example, one control gate CG can be selected by selecting one global word line GWL, selecting one select gate line SGL, and turning on the select gate transistor ST. Furthermore, by selecting one source line SL and one bit line BL, a memory cell transistor MT can be selected and operated.

By selecting and operating a single memory cell transistor MT, a read operation of data stored in the memory cell corresponding to the memory cell transistor MT and a write operation of data to the memory cell can be performed.

For example, by selecting the first global word line GWL1 and selecting the first select gate line SGL1, the first select gate transistor ST1 is turned on. By turning on the first select gate transistor ST1, the first control gate CG1 connected to the first global word line GWL1 is selected. Furthermore, by selecting the first source line SL1 and the first bit line BL1, the first memory cell transistor MT1 surrounded by the dotted line in FIG. 22 can be selected and operated.

By selecting the first global word line GWL1 and selecting the second select gate line SGL2, the fourth select gate transistor ST4 is turned on. By turning on the fourth select gate transistor ST4, the fourth control gate CG4 connected to the first global word line GWL1 is selected. Furthermore, by selecting the fourth source line SL4 and the third bit line BL3, the second memory cell transistor MT2 surrounded by the dotted line in FIG. 22 can be selected and operated.

By selecting the first global word line GWL1 and selecting the third select gate line SGL3, the seventh select gate transistor ST7 is turned on. By turning on the seventh select gate transistor ST7, the seventh control gate CG7 connected to the first global word line GWL1 is selected. Furthermore, by selecting the seventh source line SL7 and the fifth bit line BL5, the third memory cell transistor MT3 surrounded by the dotted line in FIG. 22 can be selected and operated.

The first memory cell transistor MT1, the second memory cell transistor MT2, and the third memory cell transistor MT3 are connected to the same first global word line GWL1. However, since the first memory cell transistor MT1, the second memory cell transistor MT2, and the third memory cell transistor MT3 do not share a source line SL and bit line BL, the first memory cell transistor MT1, the second memory cell transistor MT2, and the third memory cell transistor MT3 can be allowed to operate (accessed) independently. In the flash memory 200 of the second embodiment, all of the memory cells MC connected to the same global word line GWL can be accessed simultaneously.

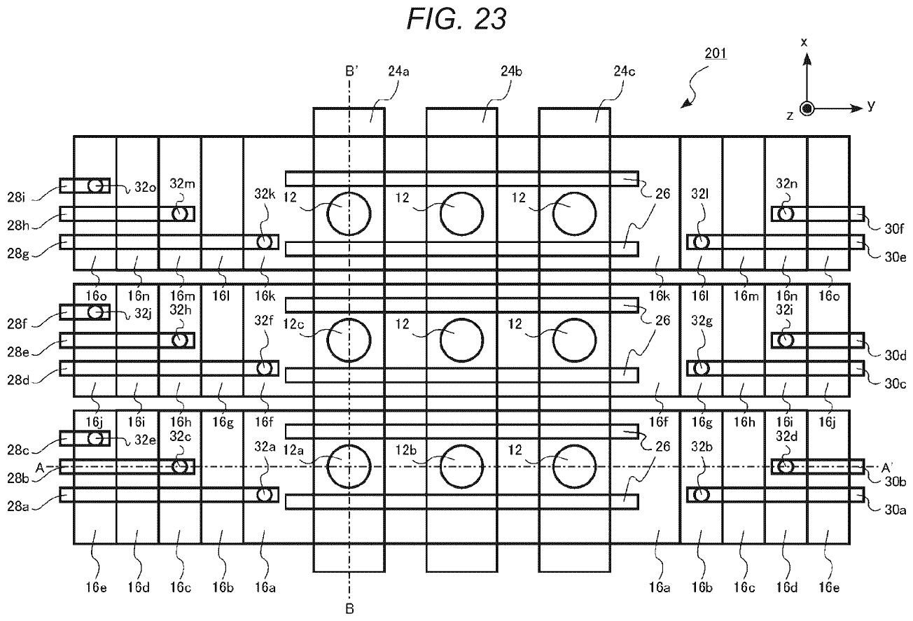

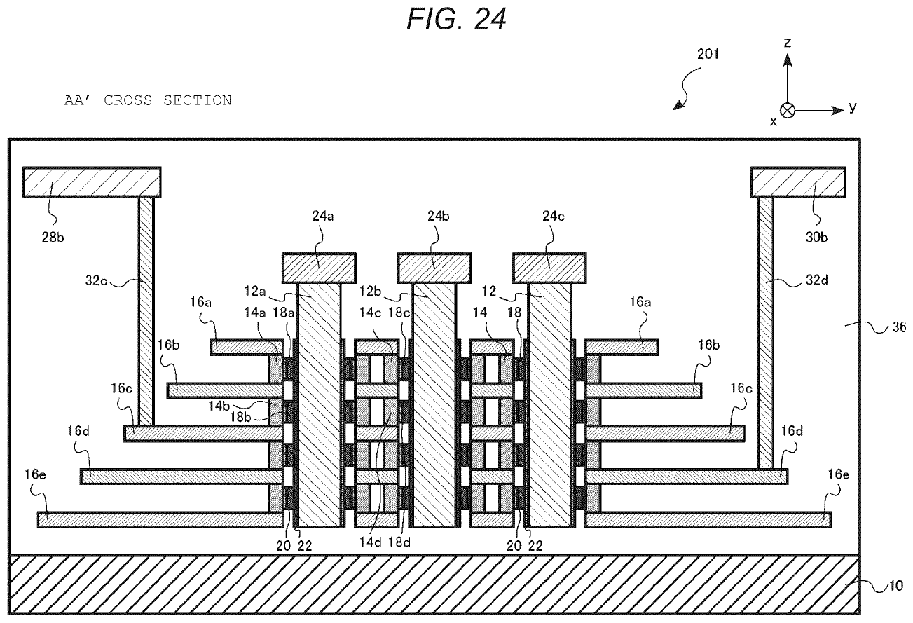

FIG. 23 is a schematic diagram of the memory cell array of the semiconductor memory device according to the second embodiment. FIG. 23 is a diagram illustrating a pattern layout of the memory cell array 201.

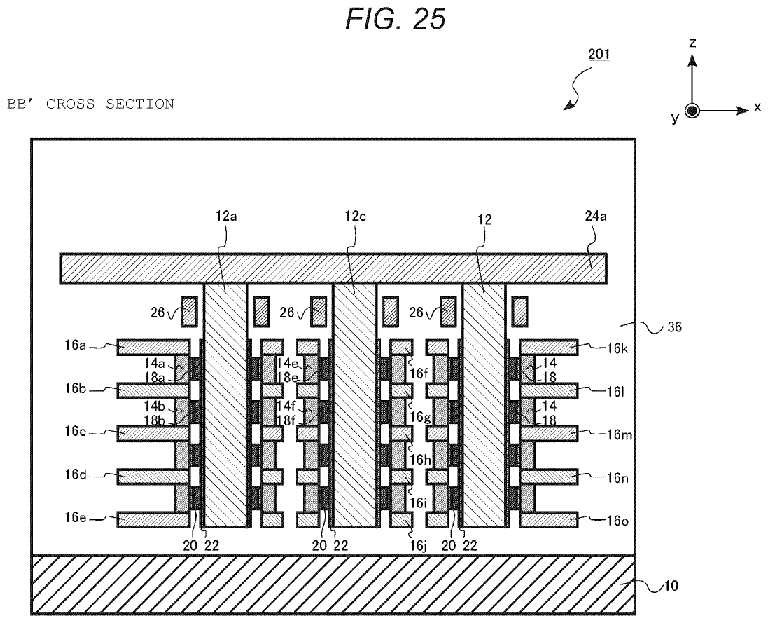

FIGS. 24 and 25 are schematic cross-sectional views of the memory cell array of the semiconductor memory device according to the second embodiment. FIG. 24 is an AA′ cross section of FIG. 23. FIG. 25 is a BB′ cross section of FIG. 23.

In FIGS. 23, 24, and 25, the x direction is an example of the third direction. The y direction is an example of a second direction. The z direction is an example of a first direction. The x, y, and z directions are orthogonal to each other.

A memory cell array 201 of a flash memory 200 of the second embodiment includes a substrate 10, a plurality of gate electrode layers 12, a plurality of semiconductor layers 14, a plurality of source/drain electrode layers 16, a plurality of charge storage layers 18, a tunnel insulating film 20, a block insulating film 22, a plurality of gate electrode wirings 24, a plurality of select gate wirings 26, a plurality of source lines 28, a plurality of bit lines 30, a plurality of contact plugs 32, and an interlayer insulating layer 36.

The tunnel insulating film 20 is an example of a first insulating film. The block insulating film 22 is an example of a second insulating film. The interlayer insulating layer 36 is an example of an insulating layer.

The plurality of gate electrode layers 12 include a first gate electrode layer 12a, a second gate electrode layer 12b, and a third gate electrode layer 12c. The first gate electrode layer 12a, the second gate electrode layer 12b, and the third gate electrode layer 12c functionally correspond to the first control gate CG1, the second control gate CG2, and the fourth control gate CG4, respectively, in the circuit diagram of FIG. 22.

The plurality of semiconductor layers 14 include a first semiconductor layer 14a, a second semiconductor layer 14b, a third semiconductor layer 14c, a fourth semiconductor layer 14d, a fifth semiconductor layer 14e, and a sixth semiconductor layer 14f.

The plurality of source/drain electrode layers 16 include a first source/drain electrode layer 16a, a second source/drain electrode layer 16b, a third source/drain electrode layer 16c, a fourth source/drain electrode layer 16d, a fifth source/drain electrode layer 16e, a sixth source/drain electrode layer 16f, a seventh source/drain electrode layer 16g, an eighth source/drain electrode layer 16h, a ninth source/drain electrode layer 16i, a tenth source/drain electrode layer 16j, an eleventh source/drain electrode layer 16k, a twelfth source/drain electrode layer 16l, a thirteenth source/drain electrode layer 16m, a fourteenth source/drain electrode layer 16n, and a fifteenth source/drain electrode layer 16o. The first source/drain electrode layer 16a is an example of a first electrode layer. The second source/drain electrode layer 16b is an example of a second electrode layer. The third source/drain electrode layer 16c is an example of a third electrode layer. The sixth source/drain electrode layer 16f is an example of a fourth electrode layer. The seventh source/drain electrode layer 16g is an example a fifth electrode layer. The eighth source/drain electrode layer 16h is an example of a sixth electrode layer.

The first source/drain electrode layer 16a, the third source/drain electrode layer 16c, the fifth source/drain electrode layer 16e, the sixth source/drain electrode layer 16f, the eighth source/drain electrode layer 16h, the tenth source/drain electrode layer 16j, the eleventh source/drain electrode layer 16k, the thirteenth source/drain electrode layer 16m, and the fifteenth source/drain electrode layer 16o functionally correspond to the first source line SL1, the second source line SL2, the third source line SL3, the fourth source line SL4, the fifth source line SL5, the sixth source line SL6, the seventh source line SL7, the eighth source line SL8, and the ninth source line SL9, respectively, in the circuit diagram of FIG. 22.

In addition, the second source/drain electrode layer 16b, the fourth source/drain electrode layer 16d, the seventh source/drain electrode layer 16g, the ninth source/drain electrode layer 16i, the twelfth source/drain electrode layer 16l, and the fourteenth source/drain electrode layer 16n functionally correspond to the first bit line BL1, the second bit line BL2, the third bit line BL3, the fourth bit line BL4, the fifth bit line BL5, and the sixth bit line BL6, respectively, in the circuit diagram of FIG. 22.

The plurality of charge storage layers 18 include a first charge storage layer 18a, a second charge storage layer 18b, a third charge storage layer 18c, a fourth charge storage layer 18d, a fifth charge storage layer 18e, and a sixth charge storage layer 18f.

The plurality of gate electrode wirings 24 include a first gate electrode wiring 24a, a second gate electrode wiring 24b, and a third gate electrode wiring 24c. The first gate electrode wiring 24a, the second gate electrode wiring 24b, and the third gate electrode wiring 24c functionally correspond to the first global word line GWL1, the second global word line GWL2, and the third global word line GWL3, respectively, in the circuit diagram of FIG. 22.

The plurality of source lines 28 include a first source line 28a, a second source line 28b, a third source line 28c, a fourth source line 28d, a fifth source line 28e, a sixth source line 28f, a seventh source line 28g, an eighth source line 28h, and a ninth source line 28i. The first source line 28a is an example of a first wiring. The second source line 28b is an example of a third wiring. The fourth source line 28d is an example of a fourth wiring. The fifth source line 28e is an example of a sixth wiring.

The first source line 28a, the second source line 28b, the third source line 28c, the fourth source line 28d, the fifth source line 28e, the sixth source line 28f, the seventh source line 28g, the eighth source lines 28h, and the ninth source lines 28i functionally correspond to the first source line SL1, the second source line SL2, the third source line SL3, the fourth source line SL4, the fifth source line SL5, the sixth source line SL6, the seventh source line SL7, the eighth source line SL8, and the ninth source line SL9, respectively, in the circuit diagram of FIG. 22.

The plurality of bit lines 30 include a first bit line 30a, a second bit line 30b, a third bit line 30c, a fourth bit line 30d, a fifth bit line 30e, and a sixth bit line 30f. The first bit line 30a is an example of a second wiring. The third bit line 30c is an example of a fifth wiring. The first bit line 30a, the second bit line 30b, the third bit line 30c, the fourth bit line 30d, the fifth bit line 30e, and the sixth bit line 30f functionally correspond to the first bit line BL1, the second bit line BL2, the third bit line BL3, the fourth bit line BL4, the fifth bit line BL5, and the sixth bit line BL6, respectively, in the circuit diagram of FIG. 22.

The plurality of contact plugs 32 include a first contact plug 32a, a second contact plug 32b, a third contact plug 32c, a fourth contact plug 32d, a fifth contact plug 32e, a sixth contact plug 32f, a seventh contact plug 32g, an eighth contact plug 32h, a ninth contact plug 32i, a tenth contact plug 32j, an eleventh contact plug 32k, a twelfth contact plug 32l, a thirteenth contact plug 32m, a fourteenth contact plug 32n, and a fifteenth contact plug 32o. The first contact plug 32a is an example of a first conductive layer. The second contact plug 32b is an example of a second conductive layer. The third contact plug 32c is an example of a third conductive layer. The sixth contact plug 32f is an example of a fourth conductive layer. The seventh contact plug 32g is an example of a fifth conductive layer. The eighth contact plug 32h is an example of a sixth conductive layer.

The structure of the memory cell MC of the flash memory 200 of the second embodiment is similar to the structure of the memory cell MC of the flash memory 100 of the first embodiment.

For example, the fifth semiconductor layer 14e is provided between the sixth source/drain electrode layer 16f and the seventh source/drain electrode layer 16g. The sixth source/drain electrode layer 16f and the seventh source/drain electrode layer 16g are in contact with the fifth semiconductor layer 14e.

For example, the sixth semiconductor layer 14f is provided between the seventh source/drain electrode layer 16g and the eighth source/drain electrode layer 16h. The seventh source/drain electrode layer 16g and the eighth source/drain electrode layer 16h are in contact with the sixth semiconductor layer 14f.

The source/drain electrode layer 16 has, for example, a plate shape.

The source/drain electrode layers 16 are divided in the z direction. An interlayer insulating layer 36 is provided between the two source/drain electrode layers 16 spaced apart and adjacent to each other in the z direction. The two source/drain electrode layers 16 spaced apart and adjacent to each other in the z direction are electrically isolated.

The source/drain electrode layers 16 are divided in the x direction. The interlayer insulating layer 36 is provided between the two source/drain electrode layers 16 spaced apart and adjacent to each other in the x direction. The two source/drain electrode layers 16 spaced apart and adjacent to each other in the x direction are electrically isolated.

For example, the interlayer insulating layer 36 is provided between the first source/drain electrode layer 16a and the sixth source/drain electrode layer 16f adjacent to each other in the x direction. For example, the interlayer insulating layer 36 is provided between the second source/drain electrode layer 16b and the seventh source/drain electrode layer 16g adjacent to each other in the x direction. For example, the interlayer insulating layer 36 is provided between the third source/drain electrode layer 16c and the eighth source/drain electrode layer 16h adjacent to each other in the x direction.

The source line 28 is provided on the source/drain electrode layer 16. The source line 28 is provided in the z direction from the source/drain electrode layer 16. The source line 28 is electrically connected to a portion of the source/drain electrode layers 16 among the plurality of source/drain electrode layers 16.

The first source line 28a is electrically connected to the first source/drain electrode layer 16a. The second source line 28b is electrically connected to the third source/drain electrode layer 16c. The third source line 28c is electrically connected to the fifth source/drain electrode layer 16e. The fourth source line 28d is electrically connected to the sixth source/drain electrode layer 16f. The fifth source line 28e is electrically connected to the eighth source/drain electrode layer 16h. The sixth source line 28f is electrically connected to the tenth source/drain electrode layer 16j. The seventh source line 28g is electrically connected to the eleventh source/drain electrode layer 16k. The eighth source line 28h is electrically connected to the thirteenth source/drain electrode layer 16m. The ninth source line 28i is electrically connected to the fifteenth source/drain electrode layer 16o.

The bit line 30 is provided on the source/drain electrode layer 16. The bit line 30 is provided in the z direction from the source/drain electrode layer 16. The bit line 30 is electrically connected to a portion of the source/drain electrode layers 16 among the plurality of source/drain electrode layers 16.

The first bit line 30a is electrically connected to the second source/drain electrode layer 16b. The second bit line 30b is electrically connected to the fourth source/drain electrode layer 16d. The third bit line 30c is electrically connected to the seventh source/drain electrode layer 16g. The fourth bit line 30d is electrically connected to the ninth source/drain electrode layer 16i. The fifth bit line 30e is electrically connected to the twelfth source/drain electrode layer 16l. The sixth bit line 30f is electrically connected to the fourteenth source/drain electrode layer 16n.

The contact plugs 32 are provided on the source/drain electrode layer 16. The contact plugs 32 extend in the z direction.

A portion of the contact plugs 32 are provided between the source/drain electrode layers 16 and the source lines 28 and electrically connect a source/drain electrode layer 16 and a source line 28.

Another portion of the contact plugs 32 are provided between the source/drain electrode layers 16 and the bit lines 30 and electrically connect a source/drain electrode layer 16 and a bit line 30.

The first contact plug 32a is provided between the first source/drain electrode layer 16a and the first source line 28a. The first contact plug 32a is electrically connected to the first source/drain electrode layer 16a and the first source line 28a.

The second contact plug 32b is provided between the second source/drain electrode layer 16b and the first bit line 30a. The second contact plug 32b is electrically connected to the second source/drain electrode layer 16b and the first bit line 30a.

The third contact plug 32c is provided between the third source/drain electrode layer 16c and the second source line 28b. The third contact plug 32c is electrically connected to the third source/drain electrode layer 16c and the second source line 28b.

The fourth contact plug 32d is provided between the fourth source/drain electrode layer 16d and the second bit line 30b. The fourth contact plug 32d is electrically connected to the fourth source/drain electrode layer 16d and the second bit line 30b.

The fifth contact plug 32e is provided between the fifth source/drain electrode layer 16e and the third source line 28c. The fifth contact plug 32e is electrically connected to the fifth source/drain electrode layer 16e and the third source line 28c.

The first contact plug 32a, the third contact plug 32c, and the fifth contact plug 32e are connected to the first end of the source/drain electrode layer 16 in the y direction. The second contact plug 32b and the fourth contact plug 32d are connected to the second end of the source/drain electrode layer 16 opposite to the first end in the y direction.

For example, a distance between the first contact plug 32a and the first gate electrode layer 12a is less than a distance between the first contact plug 32a and the second gate electrode layer 12b. In addition, a distance between the second contact plug 32b and the first gate electrode layer 12a is greater than a distance between the second contact plug 32b and the second gate electrode layer 12b. A distance between the third contact plug 32c and the first gate electrode layer 12a is less than a distance between the third contact plug 32c and the second gate electrode layer 12b.

For example, the gate electrode wiring 24 is provided between the first contact plug 32a and the second contact plug 32b in the y direction.

The sixth contact plug 32f is provided between the sixth source/drain electrode layer 16f and the fourth source line 28d. The sixth contact plug 32f is electrically connected to the sixth source/drain electrode layer 16f and the fourth source line 28d.

The seventh contact plug 32g is provided between the seventh source/drain electrode layer 16g and the third bit line 30c. The seventh contact plug 32g is electrically connected to the seventh source/drain electrode layer 16g and the third bit line 30c.

The eighth contact plug 32h is provided between the eighth source/drain electrode layer 16h and the fifth source line 28e. The eighth contact plug 32h is electrically connected to the eighth source/drain electrode layer 16h and the fifth source line 28e.

The ninth contact plug 32i is provided between the ninth source/drain electrode layer 16i and the fourth bit line 30d. The ninth contact plug 32i is electrically connected to the ninth source/drain electrode layer 16i and the fourth bit line 30d.

The tenth contact plug 32j is provided between the tenth source/drain electrode layer 16j and the sixth source line 28f. The tenth contact plug 32j is electrically connected to the tenth source/drain electrode layer 16j and the sixth source line 28f.

The sixth contact plug 32f, the eighth contact plug 32h, and the tenth contact plug 32j are connected to the first end of the source/drain electrode layer 16 in the y direction. The seventh contact plug 32g and the ninth contact plug 32i are connected to the second end of the source/drain electrode layer 16 opposite to the first end in the y direction.

For example, the gate electrode wiring 24 is provided between the sixth contact plug 32f and the seventh contact plug 32g in the y direction.

The eleventh contact plug 32k is provided between the eleventh source/drain electrode layer 16k and the seventh source line 28g. The eleventh contact plug 32k is electrically connected to the eleventh source/drain electrode layer 16k and the seventh source line 28g.

The twelfth contact plug 32l is provided between the twelfth source/drain electrode layer 16l and the fifth bit line 30e. The twelfth contact plug 32l is electrically connected to the twelfth source/drain electrode layer 16l and the fifth bit line 30e.

The thirteenth contact plug 32m is provided between the thirteenth source/drain electrode layer 16m and the eighth source line 28h. The thirteenth contact plug 32m is electrically connected to the thirteenth source/drain electrode layer 16m and the eighth source line 28h.

The fourteenth contact plug 32n is provided between the fourteenth source/drain electrode layer 16n and the sixth bit line 30f. The fourteenth contact plug 32n is electrically connected to the fourteenth source/drain electrode layer 16n and the sixth bit line 30f.

The fifteenth contact plug 32o is provided between the fifteenth source/drain electrode layer 16o and the ninth source line 28i.

The fifteenth contact plug 32o is electrically connected to the fifteenth source/drain electrode layer 16o and the ninth source line 28i.

The eleventh contact plug 32k, the thirteenth contact plug 32m, and the fifteenth contact plug 32o are connected to the first end of the source/drain electrode layer 16 in the y direction. The twelfth contact plug 32l and the fourteenth contact plug 32n are connected to the second end of the source/drain electrode layer 16 opposite to the first end in the y direction.

For example, the gate electrode wiring 24 is provided between the eleventh contact plug 32k and the twelfth contact plug 32l in the y direction.

In the memory cell array 201 of the flash memory 200 of the second embodiment, for example, in the method for manufacturing the memory cell array 201 of the first embodiment, the memory cell array 201 of the flash memory 200 is manufactured in the same manner up to the process of forming the fourth amorphous silicon film 61 in the region from which the silicon nitride layer 50 is removed (FIG. 21). After that, the fourth amorphous silicon film 61 to be the source/drain electrode layer 16 is cut off by, for example, a RIE method. By cutting off the fourth amorphous silicon film 61, the memory cell array 201 in which the source/drain electrode layers 16 are divided in the x direction can be manufactured.

It is noted that, in order to form the divided source/drain electrode layer 16 and the cut-off amorphous silicon film 61, the following method can be used. For example, before removing the silicon nitride layer 50, portions of laminated films of the silicon nitride layer 50 and the silicon oxide layer 51 are etched at positions corresponding to the cut-off regions of the source/drain electrode layers 16, and a groove cutting off the silicon nitride layer 50 is provided. After that, the silicon nitride layer 50 may be removed through this groove, and the fourth amorphous silicon film 61 may be formed in the removed portion. At this time, the fourth amorphous silicon film 61 in the grooves cutting off the silicon nitride layer 50 are removed, and the interlayer insulating layer is filled in the grooves.

In the flash memory 200 of the second embodiment, similarly to the flash memory 100 of the first embodiment, the plurality of memory cells MC are three-dimensionally arranged in the memory cell array 201, so that the degree of integration is improved.

By dividing the source/drain electrode layer 16 into portions spaced in the x direction, the plurality of memory cells connected to the same gate electrode wiring 24 and on the same xy plane do not share the same source/drain electrode layer 16 portion. In other words, the plurality of memory cells connected to the same global word line GWL and existing in the same xy plane do not share a source line SL and a bit line BL.

Therefore, the memory cells on the same xy plane and connected to the same global word line GWL can be accessed simultaneously. Therefore, as compared to the flash memory 100 of the first embodiment, random access is improved, and for example, a read speed is increased.

As described above, according to the second embodiment, a NOR flash memory capable of improving the degree of integration can be provided.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a first gate electrode layer extending in a first direction;
a first semiconductor layer surrounding the first gate electrode layer;
a second semiconductor layer in the first direction from the first semiconductor layer and surrounding the first gate electrode layer;
a first electrode layer surrounding the first gate electrode layer and in contact with the first semiconductor layer;
a second electrode layer in the first direction from the first electrode layer, the second electrode layer surrounding the first gate electrode layer and in contact with the first semiconductor layer and the second semiconductor layer, the first semiconductor layer being between the first electrode layer and the second electrode layer;
a third electrode layer in the first direction from the second electrode layer, the third electrode layer surrounding the first gate electrode layer and in contact with the second semiconductor layer, the second semiconductor layer being between the second electrode layer and the third electrode layer;
a conductive first charge storage layer between the first gate electrode layer and the first semiconductor layer; and
a conductive second charge storage layer between the first gate electrode layer and the second semiconductor layer.

2. The semiconductor memory device according to claim 1, further comprising:
an insulating layer surrounding the first semiconductor layer.

3. The semiconductor memory device according to claim 1, further comprising:
a first insulating film between the first charge storage layer and the first semiconductor layer; and
a second insulating film between the first charge storage layer and the first gate electrode layer.

4. The semiconductor memory device according to claim 1, wherein
the first electrode layer is metal, and
the second electrode layer is metal.

5. The semiconductor memory device according to claim 1, further comprising:
a second gate electrode layer extending in the first direction and spaced, in a second direction intersecting the first direction, from the first gate electrode layer;
a third semiconductor layer surrounding the second gate electrode layer, the third semiconductor layer being between the first electrode layer and the second electrode layer and in contact with the first electrode layer and the second electrode layer;
a fourth semiconductor layer in the first direction from the third semiconductor layer, the fourth semiconductor layer surrounding the second gate electrode layer and being between the second electrode layer and the third electrode layer and in contact with the second electrode layer and the third electrode layer;
a conductive third charge storage layer between the second gate electrode layer and the third semiconductor layer; and
a conductive fourth charge storage layer between the second gate electrode layer and the fourth semiconductor layer.

6. The semiconductor memory device according to claim 5, further comprising:
a first wiring in the first direction from the first electrode layer;
a first conductive layer between the first electrode layer and the first wiring and extending in the first direction, the first conductive layer being electrically connected to the first electrode layer and the first wiring;
a second wiring in the first direction from the second electrode layer;
a second conductive layer between the second electrode layer and the second wiring and extending in the first direction, the second conductive layer being electrically connected to the second electrode layer and the second wiring;
a third wiring in the first direction from the third electrode layer; and
a third conductive layer between the third electrode layer and the third wiring and extending in the first direction, the third conductive layer being electrically connected to the third electrode layer and the third wiring.

7. The semiconductor memory device according to claim 6, wherein
a distance between the first conductive layer and the first gate electrode layer is less than a distance between the first conductive layer and the second gate electrode layer,
a distance between the second conductive layer and the first gate electrode layer is greater than a distance between the second conductive layer and the second gate electrode layer, and
a distance between the third conductive layer and the first gate electrode layer is less than a distance between the third conductive layer and the second gate electrode layer.

8. The semiconductor memory device according to claim 5, further comprising:
a third gate electrode layer extending in the first direction, the third gate electrode layer being spaced, in a third direction intersecting the first direction and the second direction, from the first gate electrode layer;
a fifth semiconductor layer surrounding the third gate electrode layer, the fifth semiconductor layer being between the first electrode layer and the second electrode layer and in contact with the first electrode layer and the second electrode layer;
a sixth semiconductor layer in the first direction from the fifth semiconductor layer and surrounding the third gate electrode layer, the sixth semiconductor layer being between the second electrode layer and the third electrode layer and in contact with the second electrode layer and the third electrode layer;
a conductive fifth charge storage layer between the third gate electrode layer and the fifth semiconductor layer; and
a conductive sixth charge storage layer between the third gate electrode layer and the sixth semiconductor layer.

9. The semiconductor memory device according to claim 8, further comprising:
a first gate electrode wiring extending in the third direction;
a second gate electrode wiring extending in the third direction;
a first transistor between the first gate electrode wiring and the first gate electrode layer, the first transistor being electrically connected to the first gate electrode wiring and the first gate electrode layer;
a second transistor between the second gate electrode wiring and the second gate electrode layer, the second transistor being electrically connected to the second gate electrode wiring and the second gate electrode layer; and
a third transistor between the first gate electrode wiring and the third gate electrode layer, the third transistor being electrically connected to the first gate electrode wiring and the third gate electrode layer.

10. The semiconductor memory device according to claim 1, further comprising:
a second gate electrode layer extending in the first direction and spaced, in a second direction intersecting the first direction, from the first gate electrode layer;
a third semiconductor layer surrounding the second gate electrode layer, the third semiconductor layer being between the first electrode layer and the second electrode layer and in contact with the first electrode layer and the second electrode layer;
a fourth semiconductor layer in the first direction from the third semiconductor layer and surrounding the second gate electrode layer, the fourth semiconductor layer being between the second electrode layer and the third electrode layer and in contact with the second electrode layer and the third electrode layer;
a conductive third charge storage layer between the second gate electrode layer and the third semiconductor layer;
a conductive fourth charge storage layer between the second gate electrode layer and the fourth semiconductor layer;
a third gate electrode layer extending in the first direction and spaced, in a third direction intersecting the first direction and the second direction, from the first gate electrode layer;
a fifth semiconductor layer surrounding the third gate electrode layer;
a sixth semiconductor layer in the first direction from the fifth semiconductor layer and surrounding the third gate electrode layer;
a fourth electrode layer spaced from the first electrode layer in the third direction, the fourth electrode layer surrounding the third gate electrode layer and in contact with the fifth semiconductor layer;
a fifth electrode layer spaced from the second electrode layer in the third direction, the fifth electrode layer surrounding the third gate electrode layer and in contact with the fifth semiconductor layer and the sixth semiconductor layer, the fifth semiconductor layer being between the fourth electrode layer and the fifth electrode layer;
a sixth electrode layer spaced from the third electrode layer in the third direction, the sixth electrode layer surrounding the third gate electrode layer and in contact with the sixth semiconductor layer, the sixth semiconductor layer being between the fifth electrode layer and the sixth electrode layer;
a conductive fifth charge storage layer between the third gate electrode layer and the fifth semiconductor layer; and
a conductive sixth charge storage layer between the third gate electrode layer and the sixth semiconductor layer.

11. The semiconductor memory device according to claim 10, further comprising:
a first wiring in the first direction from the first electrode layer;
a first conductive layer between the first electrode layer and the first wiring, the first conductive layer extending in the first direction and electrically connected to the first electrode layer and the first wiring;
a second wiring in the first direction from the second electrode layer;
a second conductive layer between the second electrode layer and the second wiring, the second conductive layer extending in the first direction and electrically connected to the second electrode layer and the second wiring;
a third wiring in the first direction from the third electrode layer;
a third conductive layer between the third electrode layer and the third wiring, the third conductive layer extending in the first direction and electrically connected to the third electrode layer and the third wiring;
a fourth wiring in the first direction from the fourth electrode layer;
a fourth conductive layer between the fourth electrode layer and the fourth wiring, the fourth conductive layer extending in the first direction and electrically connected to the fourth electrode layer and the fourth wiring;
a fifth wiring in the first direction from the fifth electrode layer;
a fifth conductive layer between the fifth electrode layer and the fifth wiring, the fifth conductive layer extending in the first direction and electrically connected to the fifth electrode layer and the fifth wiring;
a sixth wiring in the first direction from the sixth electrode layer; and
a sixth conductive layer between the sixth electrode layer and the sixth wiring, the sixth conductive layer extending in the first direction and electrically connected to the sixth electrode layer and the sixth wiring.

12. The semiconductor memory device according to claim 11, wherein
a distance between the first conductive layer and the first gate electrode layer is less than a distance between the first conductive layer and the second gate electrode layer,
a distance between the second conductive layer and the first gate electrode layer is greater than a distance between the second conductive layer and the second gate electrode layer, and
a distance between the third conductive layer and the first gate electrode layer is less than a distance between the third conductive layer and the second gate electrode layer.

13. The semiconductor memory device according to claim 11, further comprising:
a first gate electrode wiring extending in the third direction;
a second gate electrode wiring extending in the third direction;
a first transistor between the first gate electrode wiring and the first gate electrode layer and electrically connected to the first gate electrode wiring and the first gate electrode layer;
a second transistor between the second gate electrode wiring and the second gate electrode layer and electrically connected to the second gate electrode wiring and the second gate electrode layer; and
a third transistor between the first gate electrode wiring and the third gate electrode layer and electrically connected to the first gate electrode wiring and the third gate electrode layer.

14. The semiconductor memory device according to claim 10, further comprising:
a first gate electrode wiring extending in the third direction;
a second gate electrode wiring extending in the third direction;
a first transistor between the first gate electrode wiring and the first gate electrode layer and electrically connected to the first gate electrode wiring and the first gate electrode layer;
a second transistor between the second gate electrode wiring and the second gate electrode layer and electrically connected to the second gate electrode wiring and the second gate electrode layer; and
a third transistor between the first gate electrode wiring and the third gate electrode layer and electrically connected to the first gate electrode wiring and the third gate electrode layer.

15. A semiconductor memory device, comprising:
a first gate electrode layer extending in a first direction;
a first semiconductor layer surrounding the first gate electrode layer;
a first electrode layer surrounding the first gate electrode layer and in contact with the first semiconductor layer;
a second electrode layer in the first direction from the first electrode layer, the second electrode layer surrounding the first gate electrode layer and in contact with the first semiconductor layer, and the first semiconductor layer being between the first electrode layer and the second electrode layer; and
a conductive first charge storage layer between the first gate electrode layer and the first semiconductor layer.

16. The semiconductor memory device according to claim 15, further comprising:
an insulating layer surrounding the first semiconductor layer.

17. The semiconductor memory device according to claim 15, further comprising:
a first insulating film between the first charge storage layer and the first semiconductor layer; and
a second insulating film between the first charge storage layer and the first gate electrode layer.

18. The semiconductor memory device according to claim 15, wherein
the first electrode layer is metal, and
the second electrode layer is metal.

19. A semiconductor memory device, comprising:
a plurality of gate electrode pillars, each extending in a first direction and spaced from each other in second and third directions perpendicular to the first direction, wherein
each respective gate electrode pillar has:
a first semiconductor layer surrounding the gate electrode pillar;
a second semiconductor layer in the first direction from the first semiconductor layer and surrounding the gate electrode pillar;
a first electrode layer surrounding the gate electrode pillar and in contact with the first semiconductor layer;
a second electrode layer in the first direction from the first electrode layer, the second electrode layer surrounding the gate electrode pillar and in contact with the first semiconductor layer and the second semiconductor layer, the first semiconductor layer being between the first electrode layer and the second electrode layer;
a third electrode layer in the first direction from the second electrode layer, the third electrode layer surrounding the gate electrode pillar and in contact with the second semiconductor layer, the second semiconductor layer being between the second electrode layer and the third electrode layer;
a conductive first charge storage layer between the gate electrode pillar and the first semiconductor layer; and
a conductive second charge storage layer between the gate electrode pillar and the second semiconductor layer.

20. The semiconductor memory device according to claim 19, wherein
the first electrode layer is metal, and
the second electrode layer is metal.
